(19) United States
(12) Patent Application Publication
(10) Pub. No.: US 2008/0157783 A1
(43) Pub. Date: Jul. 3, 2008

(54) APPARATUS AND METHOD FOR MONITORING HIGH VOLTAGE CAPACITORS

(75) Inventors: Etienne Savary, Farvagny (CH); Pierre Papaux, Farvagny (CH)

Correspondence Address: ANATOLY S. WEISER, 3525 DEL MAR HEIGHTS ROAD, #295, SAN DIEGO, CA, 92130, US

(73) Assignee: Maxwell Technologies, Inc., San Diego, CA (US)

(21) Appl. No.: 11/618,925

(22) Filed: Jan. 1, 2007

(51) Int. Cl. G01R 31/12

(52) U.S. Cl. 324/548

(57) ABSTRACT

State of a high voltage capacitor is monitored to detect partial discharge within the capacitor and approaching end-of-life of the capacitor. Partial discharge may be detected through an increased capacitance of the capacitor, and the resulting increase in the alternating current through the capacitor. Partial discharge may also be detected by presence of high frequency components in the current. Moreover, partial discharge may be detected through an increase in the internal pressure of the capacitor. When partial discharge is detected, a warning is generated, and the capacitor may be replaced in response to the warning. Periodic or random checks of the capacitor state, as indicated by the current or pressure, may also be performed. Warnings may be, for example, visual and/or audio, and may be transmitted to remote locations by radio frequency, infrared signals, or via power lines.

### FIELD OF THE INVENTION

The present invention relates generally to capacitors and methods for monitoring capacitors. More specifically, the present invention relates to monitoring of high voltage capacitors and predicting end-of-life of high voltage capacitors.

### BACKGROUND

High voltage capacitors have a number of applications, including applications in electric power transmission and distribution systems. For example, high voltage capacitors may be used in live tank breakers, dead tank breakers, capacitive voltage transformers, capacitive voltage dividers, and in gas insulated switchgear (GIS) employed in high voltage electrical transmission grids. High voltage capacitors may be installed in parallel with breaker chambers or between a phase and ground in a high voltage circuit.

Typically, a high voltage capacitor includes a number of capacitor elements connected in series between a pair of terminals within an enclosure. This is illustrated in FIG. 1, where eleven capacitor elements C₁ through C₁₁ make up the capacitor 100 within an enclosure 110. The capacitor elements C₁ through C₁₁ are connected in series between end terminals 120 and 130. Because the capacitor elements C₁ through C₁₁ are connected in series, the terminal voltage V₁ between the end terminals 120/130 is divided among the capacitor elements, as is well known to those skilled in the art. If each of the capacitor elements has substantially the same capacitance, then the voltage across each capacitor element is approximately one-eleventh of V₁.

Fewer or more than eleven capacitor elements may be present in the capacitor 100. Many capacitors include between one hundred and two hundred capacitor elements.

Partial discharge (PD) effect may take place in the individual capacitor elements that make up a high voltage capacitor. As defined in Publication 270 of the International Electrotechnical Commission (IEC), partial discharge is an electric discharge that only partially bridges the insulation between conductors, and may or may not occur adjacent to the conductors. In the present context, partial discharge can be understood as dielectric breakdown localized to a portion of electrical insulation of a capacitive element, such as one of the capacitor elements of a high voltage capacitor.

Partial discharge takes place because of the stress of electrical voltage. Partial discharge is progressive, causing deterioration of the dielectric material. In the end, partial discharge may cause complete breakdown of the dielectric material. Although new high voltage capacitors are generally free of partial discharge, partial discharge can become a problem in high voltage capacitors subjected to high stresses during their service life.

In-circuit failure of a high voltage capacitor may impair or disable the system in which the capacitor is installed, to example, an electrical power transmission or distribution system, or a part of such system. The failure may also create a safety hazard, for example, if the oil in the failed capacitor heats up and the capacitor's enclosure explodes. It would be desirable to prevent such in-circuit failures. Periodic replacement of functioning high voltage capacitors, however, is costly, particularly in view of the wide range of capacitor life spans. Therefore, it would be desirable to identify when a high voltage capacitor nears its end-of-life due to partial discharge, and to replace the capacitor before a catastrophic failure of the capacitor occurs.

### SUMMARY

A need thus exists for apparatus and methods for monitoring the state of high voltage capacitors and detecting the approach of end-of-life of such capacitors. A need also exists for methods and apparatus for detecting inchoate failures in the large installed base of high voltage capacitors, and particularly a way that would not require circuit shutdown or isolation of the capacitor from the circuit in which the capacitor is installed. A need further exists for providing high voltage capacitors with built-in mechanisms for providing an indication of the approaching end-of-life.

Various embodiments of the present invention are directed to methods and apparatus for monitoring capacitors. In an embodiment, a method is provided for monitoring state of a high voltage capacitor that includes a plurality of capacitor elements. The method includes measuring current through the capacitor to obtain measured current, and comparing the measured current to a threshold. The method further includes generating an indication of capacitor failure in response to the measured current increasing above the threshold.

In accordance with selected aspects of the invention, the capacitor may be removed from a circuit in response to the indication of capacitor failure.

In accordance with selected aspects of the invention, the indication of capacitor failure may be transmitted to a remote location, for example, by using a radio frequency signal.

In accordance with selected aspects of the invention, at least one step of the step of measuring, comparing, generating and transmitting is performed in response to an interrogation request received from the remote location or another place.

In accordance with selected aspects of the invention, the measured current is current at grid frequency, and the threshold is set so that shorting of four percent of the capacitor elements would cause generation of the indication of capacitor failure.

In an embodiment, a method of monitoring the state of a high voltage capacitor includes measuring high frequency components of the current through the capacitor. The high frequency components fall within a predetermined bandwidth associated with partial discharge arcing. The method further includes combining the high frequency components of the current through the capacitor within the predetermined bandwidth, and comparing the combined high frequency current to a threshold. In response to the combined high frequency current exceeding the threshold, an indication of capacitor failure is generated.

In accordance with selected aspects of the invention, the capacitor may be removed from a circuit in response to the indication of capacitor failure.

In accordance with selected aspects of the invention, the indication of capacitor failure may be transmitted to a remote location, example, by sending a radio frequency signal.

In accordance with selected aspects of the invention, at least one step of the step of measuring, the step of comparing, the step of combining, the step of generating, and the step of transmitting is performed in response to an interrogation request, which may be received from the remote location or another place.

In an embodiment, a method is provided for monitoring the state of a high voltage capacitor that includes a sealed enclosure and a number of capacitor elements within the enclosure. The method includes measuring pressure within the enclosure, and comparing the measured pressure to a threshold. The method further includes generating an indication of capacitor failure in response to the measured pressure exceeding the threshold.

In accordance with selected aspects of the invention, the capacitor may be removed from a circuit in response to the indication of capacitor failure.

In accordance with selected aspects of the invention, the threshold may be set at ten percent of the rated pressure of the enclosure, at or above ten bars, or at or above twenty bars.

In accordance with selected aspects of the invention, the indication of capacitor failure may be transmitted to a remote location, for example, by sending a radio frequency signal.

In selected aspects of the invention, at least one step of the step of measuring, the step of comparing, the step of combining, the step of generating, and the step of transmitting is performed in response to an interrogation request, which may be received from the remote location or another place.

In an embodiment, apparatus for monitoring state of a high voltage capacitor includes a current meter, and a processing module coupled to the current meter. The current meter is configured to measure current through the capacitor. The processing, module includes a comparator configured to compare the measured current to a threshold, and to generate an indication of capacitor failure in response to the measured current exceeding the threshold.

In an embodiment, apparatus for monitoring state of a high voltage capacitor includes a current sampler, and a processing module coupled to the current sampler. The current sampler is configured to measure high frequency components of current through the capacitor, within a predetermined bandwidth. The processing module includes a combining circuit configured to combine the measured high frequency components to obtain the combined high frequency current, and a comparator configured to compare the combined high frequency current to a threshold, and to generate an indication of capacitor failure when the combined high frequency current exceeds the threshold.

In selected aspects of the invention, the apparatus embodiments may be integrated with the monitored capacitor. The capacitor may be part of a live tank breaker, dead tank breaker, or gas insulated switchgear.

These and other features and aspects of the present invention will be better understood with reference to the following description, drawings, and appended claims.

### DESCRIPTION OF THE FIGURES

FIG. 1 illustrates a high voltage capacitor with multiple capacitor elements.

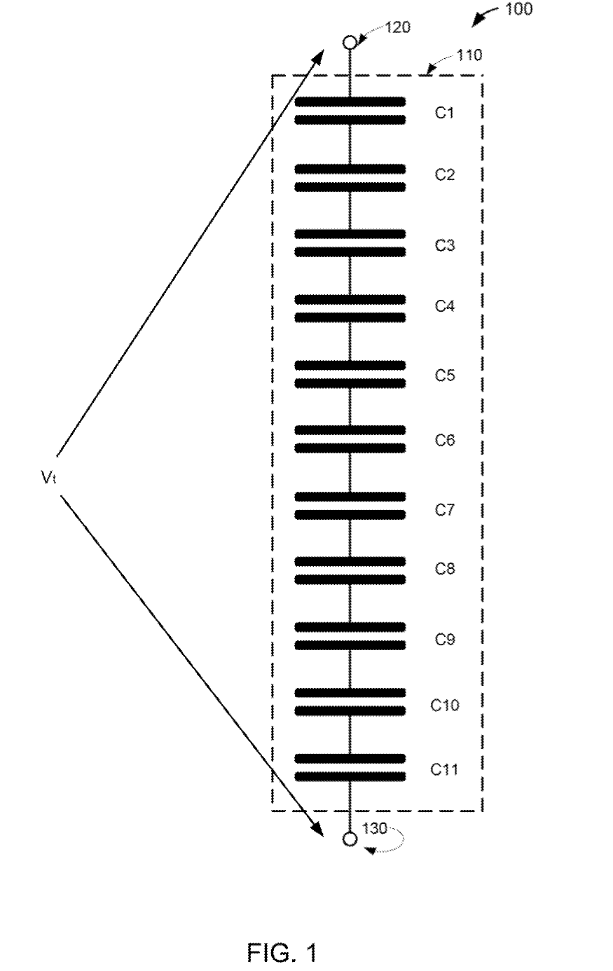

FIG. 2 is a high-level schematic diagram illustrating a combination in which the state of a high voltage capacitor is monitored for by a current meter and a processing module, in accordance with selected aspects of the present invention;

FIG. 3 is a high-level schematic diagram illustrating a processing module used to monitor the state of a high voltage capacitor, in accordance with selected aspects of the present invention:

FIG. 4 is a high-level schematic diagram illustrating a combination in which the state of a high voltage capacitor is monitored by a current sampler and a processing module, in accordance with selected aspects of the present invention; and

FIG. 5 is a high-level schematic diagram illustrating a combination in which the state of a high voltage capacitor is monitored by a pressure sensor and a processing module, in accordance with selected aspects of the present invention.

### DETAILED DESCRIPTION

In this document, the words “embodiment” and “variant” refer to particular apparatus, process, or article of manufacture, and not necessarily to the same apparatus, process, or article of manufacture. Thus, “one embodiment,” “one variant,” or a similar expression used in one place or context can refer to a particular apparatus, process, or article of manufacture; the same or a similar expression in a different place can refer to a different apparatus, process or article of manufacture. The expression “alternative embodiment” and similar phrases are used to indicate one of a number of different possible embodiments. The number of possible embodiments is not necessarily limited to two or any other quantity. Characterization of an embodiment as “exemplary” means that the embodiment is used as an example. Such characterization does not necessarily mean that the embodiment is a preferred embodiment; the embodiment may but need not be a currently preferred embodiment.

The words “couple,” “connect,” and similar expressions with their inflectional morphemes do not necessarily import an immediate or direct connection, but include connections through mediate elements within their meaning.

A “capacitor” and particularly a “high voltage capacitor” may include multiple “capacitor elements” connected in parallel, in series, or in both parallel and series combinations, between a pair of terminals of the capacitor. Typically, the capacitor elements of the capacitor are contained within an enclosure, which may be sealed. The enclosure provides external access to the terminals of the capacitor. Construction of high voltage capacitors is also described in a commonly-assigned patent application entitled HIGH VOLTAGE CAPACITOR AND METHOD FOR MANUFACTURING SAME, Attorney Docket Number HVC05.001GEN. filing date Dec. 22, 2006, Express Mail Label EQ 580956017 US, which is hereby incorporated by reference as if fully set forth herein, including tables and claims. In some applications, high voltage capacitors are designed for voltages of at least seventy kilovolts; in some applications, such capacitors are designed for voltages of at least one hundred and ten kilovolts; in some applications, such capacitors are designed for voltages of at least five hundred kilovolts; in some applications, such capacitors are designed for voltages of at least seven hundred kilovolts.

“Transmission grid” or simply “grid” refers to a high-voltage network for long-distance electric power transmission. Grid frequency is typically between hertz (e.g., in the European Union) and sixty hertz (e.g. in the United States). Grid voltage are typically over seventy kilovolts.

“High frequency” refers to a frequency caused by partial discharge within a high voltage capacitor, which is considerably higher than the grid frequencies. Typically, such frequencies fall above kilohertz range.

Other and further definitions and clarifications of definitions may be found throughout this document. All the definitions are intended to assist in understanding this disclosure and the appended claims, but the scope and spirit of the invention should not necessarily be construed as strictly limited to the definitions, or to the particular examples described in this specification.

In this document, reference will be made in detail to several embodiments of the invention that are illustrated in the accompanying drawings. Sane reference numerals may be used in the drawings and the description to refer to the same components or steps. The drawings are in a simplified form and not to precise scale. For purposes of convenience and clarity, directional terms, such as top, bottom, left, right, up, down, over, under, above, below, beneath, rear, and front may be used with respect to the accompanying drawings. These and similar directional terms should not be construed to limit the scope of the invention.

In a typical failure mode of a high voltage capacitor, at least one of the capacitor elements of the capacitor fails because of partial discharge. If the failed capacitor element shorts out as a result of the failure, the terminal voltage of the capacitor is divided among the remaining, still functioning capacitor elements of the same capacitor. Each of the remaining functioning elements is then subjected to a higher voltage, with the accompanying higher stress level and increased rate of partial discharge. Subjected to the higher stress levels, additional elements fail, and the progression of failures of the individual elements accelerates until a catastrophic failure of the capacitor takes place.

If the failed capacitor element does not short out, partial discharge or arcing across the failed element often results.

Note that failure of one or more individual capacitor elements may signal approaching end-of-life of the capacitor even in the absence of an increase in the stress levels of the remaining capacitor elements. One reason for this is that the different capacitor elements were likely manufactured at the same time, through the same process, and using the same materials and components. Further, the capacitor elements have spent their lives in the same enclosure, subjected to the same or highly-correlated environmental stresses, such as temperatures and terminal voltages. Therefore the remaining elements have aged similarly to the failed capacitor element(s). Thus, even when the failed capacitor element or elements do not short out, such failures may be used as indications of approaching end-of-life of the capacitor. Moreover, capacitor performance may be deleteriously affected by arcing in a capacitor element of the capacitor. Therefore, replacement of the capacitor with an arcing element may be indicated even if catastrophic failure of the capacitor is not imminent.

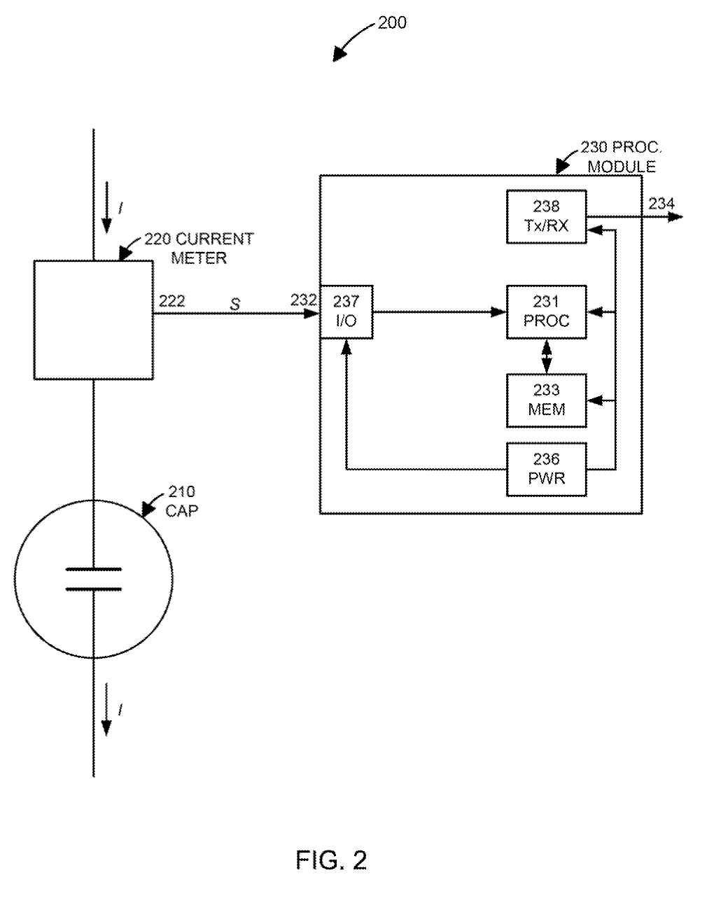

Referring more particularly to the drawings, FIG. 2 is a high-level schematic diagram illustrating a combination 200 in which the state of a high voltage capacitor 210 is monitored by a current meter 220 and a processing module 230.

The current meter 220 may be a shunt-type current meter, or a meter installed in series with the capacitor 210, so that the current I through the capacitor 210 also flows through the current meter 220, generating a current indication signal S at an output 222 of the current meter 220. Such current meters configured to measure alternating currents flowing through them are known to those skilled in the art. The current meter 220 may also surround a conductor through which the current I flows, and measure the current I indirectly, i.e., through measurement of the magnetic field around the conductor. Indirect measurement may be particularly advantageous when the monitored capacitor may, not be readily disconnected from the circuit in which it is installed. Magnetic current meters are also known to those skilled in the art.

The processing module 230 receives the signal S at an input 232, analyzes the signal S, and, based on the analysis, generates an indication of capacitor state (e.g., failure, non-failure, or a reading indicative of the actual present state of the capacitor) at an output 234. In the illustrated embodiment, the processing module 230 is based on a processor 231 executing program code stored in one or more program memory modules 233. The processor may be, for example, a general purpose microprocessor or microcontroller, or an application-specific device. An advantage of using general purpose microcontrollers is wide availability and reasonable cost of such devices, and their ability to perform many of the functions within the processing module 230 without requiring additional devices. The program code may be stored in separate memory modules, as shown in FIG. 2, or within the processor 231. The memory modules of the processing module 230 may also include non-volatile writable memory for storing various parameters, such history of the current through the capacitor 210. The non-volatile memory also be included within the processor 231.

The processing, module 230 further includes a power supply 236. By way of examples, the power supply may be (1) a primary, or secondary battery, (2) a conversion circuit configured to generate voltage for operation of the processing module 230 from the high voltage of the system in which the capacitor 210 is installed, (3) a fuel cell device (4) a photoelectric device, or (5) a combination of such devices. In addition to providing power to the processing module 230, the power supply 236 may also provide power to the current meter 220 and/or other optional devices in the combination 200. Indeed, the current meter 220 may be integrated with the processing module 230.

The processor 231 operates under control of the program code to read the signal S from the current meter 220 through an interface circuit 237 (e.g., an analog-to-digital converter or general purpose I/O), analyze the signal S, and transmit an indication of capacitor state to a local or a remote location through a transceiver (transmitter-receiver pair) 238. The transceiver 238 may transmit the indication via a wired connection, infrared (IR) or radio frequency (RF) radiation, by modulating a signal on power lines of the system in which the capacitor 210 is installed, or otherwise. In a variant, the transceiver 238 is an Echelon®-compliant device. In a variant, the transceiver 238 transmits the indication in accordance with the Bluetooth® standard. The transmitted indication may be an alarm code, an alive-and-well code (i.e., an indication of non-failure or normally-functioning capacitor), or information indicative of the actual reading of the current meter 220 or of the capacitance computed from the reading of the current meter 220, particularly where the voltage across the capacitor 210 is known. The transmitted indication may also be a combination of an alarm or alive-and-well code with additional information.

In a variant, the processing module 230 provides the indication of capacitor state in response to a remote interrogation request received through the transceiver 238, for example, an RF/IR interrogation signal received through the transceiver 238 from an external control circuit.

In another embodiment, the indication of capacitor state is a visual or an audio indication. For example, the indication may include activation of a light emitter such as a light emitting diode (LED), or changing of the color of the LED or another light emitter. The indication of capacitor state may also be displayed on an alphanumeric display device, for example, as an alphanumeric warning or a display of the actual reading of the current meter 220 or of the capacitance computed from the reading of the current meter 220. The indication of capacitor state may also be an audio warning, for example, sound generated by activation of a buzzer or a similar sounding device.

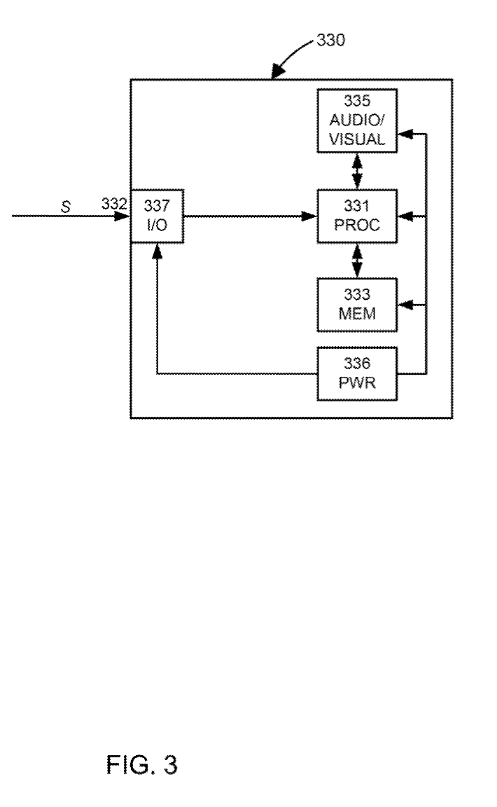

An exemplary processing module 330 of an embodiment implementing audio/visual warning is illustrated in FIG. 3, in a high-level, schematic diagram manner. The processing module 330 is similar to the module 230. It includes a processor 331, memory module(s) 333, a power supply 336, and an interface circuit 337, which are identical or analogous to the similarly-named components of the processing module 230 shown in FIG. 2. Here, however, an audio/visual warning device 335 replaces the transceiver 238 of the processing module 230 of FIG. 2. The indication of capacitor state may be provided in response to detection of an approaching end-of-life of the monitored capacitor (e.g., violation of a threshold by the current I), or in response to an interrogation signal. For example, a manual input device such as a button (not shown) may be provided, and the processing module 330 may show or sound the capacitor's state using the warning device 335 in response to an input signal received from the manual input device.

It should be noted that indications of capacitor state may be provided in multiple modes. For example, a processing module may include a sounder for generating an audio warning, an LED for visual warning, and an RF transmitter for sending the indication of capacitor state to a remote location.

In some variants, an increase in the current I through the monitored high voltage capacitor (e.g., the capacitor 210) over a predetermined threshold current value triggers an alarm. In a more specific embodiment, the predetermined threshold is set so that shorting of four percent of the capacitor elements of the capacitor would cause triggering of the alarm or another indication of capacitor failure.

In variants, an increase in the current I over a dynamically determined threshold triggers an alarm. The dynamically determined threshold may be based, for example, on an average of the current I during a base period, and on historical volatility of the current I. For example, the threshold may be set by adding a predetermined amount to the average current, or by adding an amount related to the volatility to the average current, to guarantee that the volatility, comparable to the previously-measured volatility will not trigger an alarm. The average may be determined during a fixed duration time period following initial installation of the capacitor, or flowing installation of the processing module in combination with the currents meter. The volatility and the average current may be measured at the same time, or the volatility may be updated during the life time of the capacitor. The increase of the current I that triggers an alarm may be a short-duration increase. For example, any increase over the threshold (predetermined or dynamic) may trigger the alarm. Alternatively, the increase over the threshold may need to be sustained (either at all times or on average) for some predetermined time duration, in order to trigger an alarm.

Some combination of dynamic and predetermined thresholds may also be used. For example, an alarm may be generated if a first predetermined threshold is violated by the current I, or if a second dynamically-determined threshold is violated by I. Similarly, averaged I values may be used together with instantaneous I values. For example, an alarm may be triggered when instantaneous current sensor output at any time exceeds a relatively high threshold, and also when time-averaged current sensor output exceeds a somewhat lower threshold.

As we have already mentioned, arcing may occur when one or more capacitor elements fail within a high voltage capacitor. Arcing may (but need not necessarily) increase the current through the capacitor to a degree sufficient to trigger a warning and/or indication of capacitor failure. Additionally, arcing tends to generate frequency oscillations of the current in frequency ranges considerably higher than grid frequencies of 50-60 Hertz. Some embodiments use this property and monitor high frequency components in the current I to detect the approaching end-of-life of a high voltage capacitor.

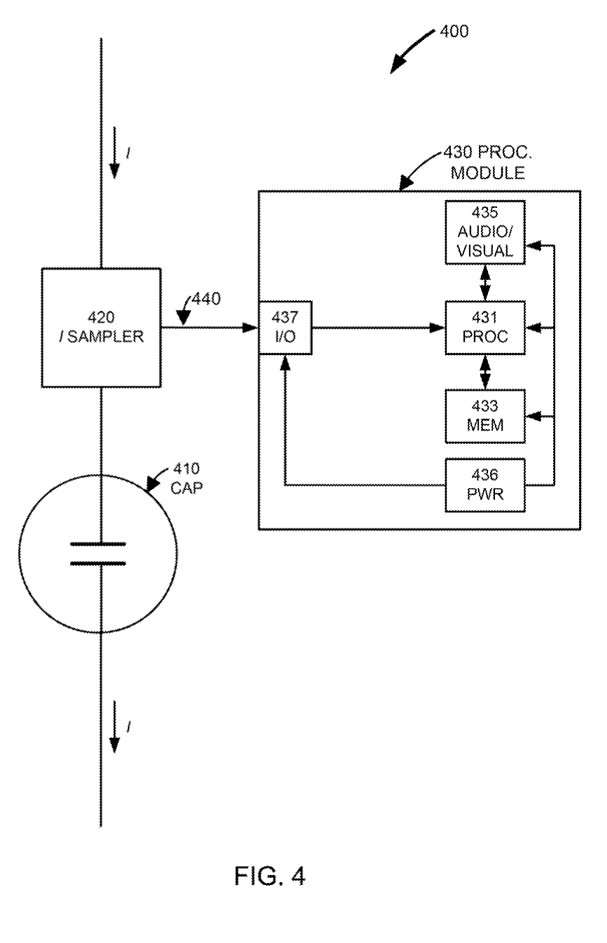

FIG. 4 illustrates one such combination 400 in a high level, schematic diagram manner. The combination 400 is similar to the combination 200. It includes a high voltage capacitor 410 monitored for indications of end-of-life by a current sampler 420 connected to a processing module 430 by a connection 440. The sampler 420 obtains samples of the alternating current I through the capacitor 410 and transmits the samples to the processing module 430 via the connection 440. The structure of the processing module 430 may be quite similar to that of the processing modules 230/330, including a processor 431 that executes program code stored in one or more program memory modules 433, a power supply 436, an audio/visual warning device 435, and an interface circuit 437. These components may be the same or similar to the processor 331, memory module(s) 333, power supply 336, interface circuit 337, and warning device 335 described in connection with FIG. 3. The interface circuit 437 allows the processor 431 to communicate with the sampler 420 via the connection 440, which may be, for example, a simple wire connection, a parallel data bus, or a serial data busy. As in the other embodiments, a microcontroller may perform many or possibly all of the functions of the processing module 430 and of the sampler 420. For example, the microcontroller may include one or more general purpose input/output (I/O) lines for reading the digitized samples of a voltage produced by the current I.

In some variants of the combination 400, an indication of capacitor failure is triggered when the processing module 430 determines that the combined current components of the current I through the monitored capacitor 410 within a predetermined frequency band (i.e., the combined band-limited high frequency current components) exceed a predetermined percentage of the current I at the grid frequency. The indication of capacitor failure may be triggered whenever the processing module 430 determines that the combined band-limited high frequency current components exceed the predetermined percentage of the grid current.

$${\int }_{BW} I \cdot d f > ( PercentThreshold ) \cdot {I}_{GridFreq} ,$$

where I_{GridFreq} is the grid component, and the integral or summation of the current I is taken over the high frequency band of interest.

The indication of capacitor failure may also be triggered when the processing module 430 determines that the average of the combined band-limited high frequency current components exceeds the predetermined percentage of the grid current:

$$[ {\int }_{Δ T} {\int }_{BW} {I}_{HF} \cdot d f ] \cdot d t ] > ( PercentThreshold \cdot {I}_{GridFreq} \cdot Δ T ) ,$$

where the integrals/summations are taken over the frequencies of interest (BW) and a predetermined or dynamically determined time period, (ΔT).

In the above formulas, the grid current (I_{GridFreq}) may also be averaged over a time interval.

In some variants, the instantaneous and averaged approaches are combined in a manner similar to that discussed above in relation to the current meter embodiments. For example, an indication of capacitor failure may be triggered whenever the instantaneous combined band-limited high frequency current components exceed a first threshold, or whenever the time-averaged combined band-limited high frequency current components exceed a second threshold.

In some variants, the high frequency band over which the high frequency current components are measured and integrated/summed includes 100 KHz. In some variants, the width of the band is approximately 50 KHz. In some variants, the width of the band is approximately 20 KHz. In some variants, the width of the band is approximately 10 KHz. In some variants, the band extends between 50 KHz and 150 KHz, 90 KHz and 110 KHz, and 95 and 105 KHz. Of course, the invention need not exclude the use of other center frequencies and bandwidths.

The sampler 420 is not limited to obtaining samples of the current I directly, but may also (or instead) obtain samples of the electromagnetic emissions in the frequency band(s) of interest. In variants using this approach, it may be desirable to rely more on the averaged spectral samples, because of the potential presence of electromagnetic interference within the band(s). In such variants, the sampler 420 may include, for example, a sensor of electromagnetic radiation. The detector may be similar to antennae of AM radios.

Partial discharge in one or more capacitor elements may result in dissipation of additional energy in the high voltage capacitor that includes the element or elements. The temperature of the oil inside the capacitor may increase as a result of the energy dissipation, and oil vapors may then raise the pressure within the sealed enclosure of the capacitor. Some embodiments use this property to monitor the state of the capacitor and detect approaching end-of-life of the capacitor.

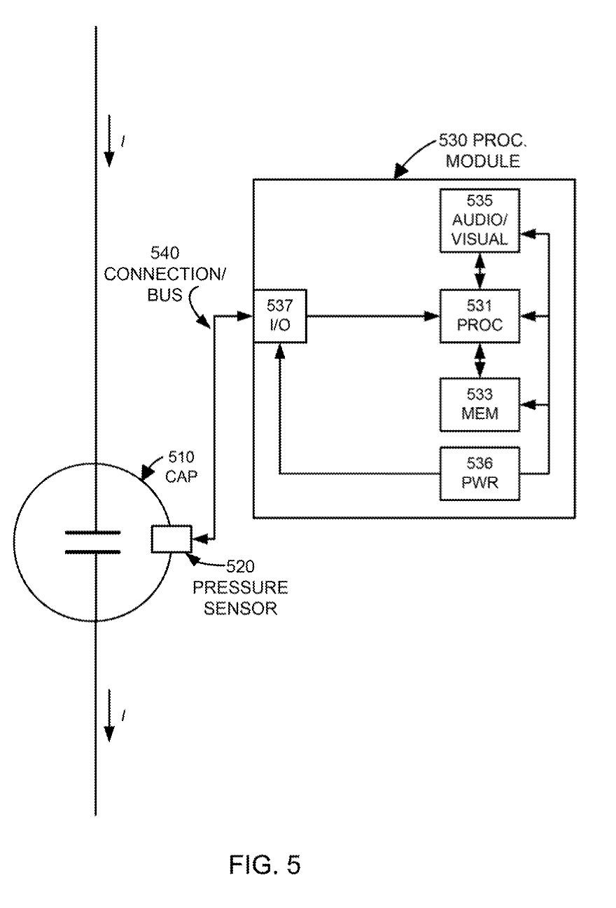

FIG. 5 illustrates one such combination 500 in a high level schematic diagram manner. The combination 500 is also similar to the combination 200. It includes a high voltage capacitor 510 monitored by a pressure sensor 520 connected to a processing module 530 through a connection 540. The pressure sensor 520 may be incorporated into a cover of the enclosure of the capacitor 510, and may be integrated with a pressure release vent. It samples the internal pressure within the enclosure of the capacitor 510 generates a signal representing the pressure, and transmits the signal to the processing module 530 via the connection 540. The processing module 530 may be quite similar or identical to the processing modules 230/330/430, including a processor 531, memory 533, a power supply 536, I/O 537, and an audio/visual warning device 535. The connection 540 may include a simple wire allowing the processor 531 to read the output of the pressure sensor 520, or it may be a parallel or serial data bus.

The pressure level at which an indication of capacitor failure is triggered may be set above the highest internal pressure of the capacitor 510 expected throughout the life of the capacitor 510. In some variants, the triggering pressure level is set at or above ten bars. (One bar is 100.000 pascals.) In some more specific variants, the triggering pressure level is set at or above twenty bars. Is some variants, the triggering, pressure is set at or above ten percent of the rated pressure of the enclosure of the capacitor 510.

Advantageously, the current/pressure detectors or sensors (e.g., the detectors/sensors 220/420/520) and/or the processing modules (e.g., the processing modules 230/330/430/530) maw be integrated with the capacitor that is being monitored, for example, within the same enclosure, or by attaching the detector/sensor and the processing module to the capacitor's enclosure.

In making the various comparisons of signals and thresholds, the processors of the processing modules may in effect function as one or more digitally-implemented comparators. It should be understood, however, that the invention is not necessarily limited to microprocessor- or microcontroller-based processing modules, or even to digital processing modules. A processing module may be implemented as one or more analog or digital comparators that compare a signal received from a sensor (e.g., from a current meter, current sampler, or pressure sensor) to one or more thresholds, triggering an indication of capacitor failure when a threshold is violated, or when a plurality of thresholds are violated. Similarly, two or more comparators may be used to compare the sensor signal and an average of the sensor signal (or another signal derivative) to two thresholds.

The inventive high voltage capacitors, apparatus for monitoring the capacitors, and methods for monitoring the capacitors have been described above in considerable detail. This was done for illustration purposes. Neither the specific embodiments of the invention as a whole, nor those of its features limit the general principles uderlying the invention. In particular, the invention is not necessarily limited to the specific currents, frequencies energy levels, or pressures mentioned. Furthermore, the apparatus described may be multiplexed to monitor multiple high voltage capacitors at the same time, and multiple monitoring methods may be used to monitor one or several capacitors. The capacitors and the monitoring apparatus may be installed in live tank breakers, dead tank breakers, gas insulated switchgear, and other devices. The specific features described herein may be used in some embodiments, but not in others, without departure from the spirit and scope of the invention as set forth. Many additional modifications are intended in the foregoing disclosure, and it will be appreciated by those of ordinary skill in the art that, in some instances, some features of the invention will be employed in the absence of a corresponding use of other features. The illustrative examples therefore do not define the metes and bounds of the invention and the legal protection afforded the invention, which function is served by the claims and their equivalents.

1. A method of monitoring state of a high voltage capacitor comprising a plurality of capacitor elements, the method comprising:
measuring current through the capacitor to obtain measured current;
comparing the measured current and a threshold; and
in response to the measured current exceeding the threshold, generating an indication of capacitor failure.

2. A method according to claim 1, further comprising removing the capacitor from a circuit in response to the indication of capacitor failure.

3. A method according to claim 2, wherein the indication comprises a sound indication, and the step of generating comprises producing the sound indication.

4. A method according to claim 2, wherein the indication comprises a visual indication, and the step of generating comprises producing the visual indication.

5. A method according to claim 2, wherein the indication comprises an alphanumeric visual indication, and the step of generating comprises producing the alphanumeric visual indication.

6. A method according to claim 1, further comprising transmitting the indication of capacitor failure to a remote location.

7. A method according to claim 6, wherein the step of transmitting comprises sending a radio frequency signal.

8. A method according to claim 7, further comprising:
receiving an interrogation request;
wherein at least one step of the step of measuring, comparing, generating, and transmitting is performed in response to the interrogation request.

9. A method according to claim 8, wherein the step of receiving comprises receiving the interrogation request from the remote location.

10. A method according to claim 1, further comprising establishing the threshold.

11. A method according to claim 10, wherein the step of establishing comprises setting the threshold based on an average current through the capacitor during a base time period.

12. A method according to claim 10, wherein the step of establishing comprises setting the threshold based on an average current through the capacitor during a base time period and based on volatility of the current through the capacitor during the base period.

13. A method according to claim 1, wherein the current is current at grid frequency, the step of measuring is performed indirectly, and the threshold is set so that shorting of four percent of the capacitor elements would cause generation of the indication of capacitor failure.

14. A method of monitoring state of a high voltage capacitor, the method comprising:
measuring high frequency components of current through the capacitor within a predetermined bandwidth;
combining the high frequency components of the current through the capacitor within the predetermined bandwidth to obtain combined high frequency current;
comparing the combined high frequency current and a threshold; and
in response to the combined high frequency current exceeding the threshold, generating an indication of capacitor failure.

15. A method according to claim 14, further comprising removing the capacitor from a circuit in response to the indication of capacitor failure.

16. A method according to claim 14, further comprising transmitting the indication of capacitor failure to a remote location.

17. A method according to claim 16, wherein the step of transmitting comprises sending a radio frequency signal.

18. A method according to claim 17, further comprising:
receiving an interrogation request;
wherein at least one step of the step of measuring, the step of comparing, the step of combining, the step of generating, and the step of transmitting is performed in response to the interrogation request.

19. A method according to claim 18, wherein the step of receiving comprises receiving the interrogation request from the remote location.

20. A method according to claim 14, further comprising establishing the threshold.

21. A method according to claim 14, wherein the bandwidth extends substantially between 50 and 150 KHz.

22. A method according to claim 14, wherein the bandwidth extends between 90 and 110 KHz.

23. A method according to claim 14, wherein the bandwidth extends between 95 and 105 KHz.

24. A method according to claim 14, wherein the step of measuring is performed indirectly.

25. A method of monitoring state of a high voltage capacitor, the capacitor comprising a sealed enclosure and a plurality of capacitor elements within the enclosure, the method comprising:
measuring pressure within the enclosure to obtain measured pressure;
comparing the measured pressure and a threshold; and
in response to the measured pressure exceeding the threshold, generating an indication of capacitor failure.

26. A method according to claim 25, further comprising removing the capacitor from a circuit in response to the indication of capacitor failure.

27. A method according to claim 26, wherein the threshold is set substantially at ten percent of the rated pressure of the enclosure.

28. A method according to claim 26, wherein the threshold is set substantially at ten bars.

29. A method according to claim 26, wherein the threshold is set substantially at twenty bars.

30. A method according to claim 25, further comprising transmitting the indication of capacitor failure to a remote location.

31. A method according to claim 30, wherein the step of transmitting comprises sending a radio frequency signal.

32. A method according to claim 31, further comprising:
receiving an interrogation request;
wherein at least one step of the step of measuring, comparing, generating, and transmitting is performed in response to the interrogation request.

33. An apparatus for monitoring state of a high voltage capacitor comprising a plurality of capacitor elements, the apparatus comprising:
a current meter configured to measure current through the capacitor to obtain measured current;
a processing module coupled to the current meter, the processing module comprising:
a comparator configured to compare the measured current and a threshold, and to generate an indication of capacitor failure in response to the measured current exceeding the threshold.

34. An apparatus according to claim 33, wherein the processing module further comprises a sounder activated by the indication of capacitor failure.

35. An apparatus according to claim 33, wherein the processing module further comprises a visual indicator configured to display the indication of capacitor failure.

36. An apparatus according to claim 33, wherein the processing module further comprises a transmitter configured to transmit the indication of capacitor failure to a remote location.

37. An apparatus according to claim 36, wherein the transmitter is a radio frequency transmitter.

38. An apparatus according to claim 37, wherein the processing module further comprises a receiver configured to receive an interrogation request, and the transmitter is configured to transmit the indication in response to the interrogation request.

39. An apparatus according to claim 33, wherein the comparator comprises an analog comparator.

40. An apparatus according to claim 33, wherein the comparator is implemented in a processor configured to execute program code stored in a memory module.

41. An apparatus according to claim 40, wherein the processor comprises the memory module.

42. An apparatus according to claim 40, wherein, when the processor executes the program code, the program code causes the processor to set the threshold.

43. An apparatus according to claim 40, wherein, when the processor executes the program code, the program code causes the processor to set the threshold based on an average current through the capacitor during a base time period.

44. An apparatus according to claim 40, wherein, when the processor executes the program code, the program code causes the processor to set the threshold based on (1) an average current through the capacitor during a base time period, and (2) volatility of the current through the capacitor during the base time period.

45. An apparatus according to claim 33, wherein the current meter is configured to measure indirectly the current at grid frequency, and the threshold is set so that shorting of four percent of the capacitor elements would cause generation of the indication of capacitor failure.

46. An apparatus according to claim 33, further comprising the capacitor.

47. A live tank breaker comprising the apparatus of claim 33 and the capacitor.

48. A dead tank breaker comprising the apparatus of claim 33 and the capacitor.

49. An apparatus for monitoring state of a high voltage capacitor, the apparatus comprising:
a current sampler configured to measure high frequency components of current through the capacitor within a predetermined bandwidth, thereby obtaining measured high frequency components;
a processing module coupled to the current sampler, the processing module comprising:
a combining circuit configured to combine the measured high frequency components, thereby obtaining combined high frequency current;
a comparator configured to compare the combined high frequency current with a threshold, and to generate an indication of capacitor failure in response to the combined high frequency current exceeding the threshold.

50. An apparatus according to claim 49, wherein the processing module further comprises a radio frequency transmitter configured to transmit the indication of capacitor failure.

51. An apparatus according to claim 50, wherein the processing module further comprises a radio frequency receiver configured to receive an interrogation request, and the transmitter is configured to transmit the indication in response to the interrogation request.

52. An apparatus according to claim 49, wherein the comparator and the combining circuit are implemented in a processor configured to execute program code stored in a memory module.

53. An apparatus according to claim 52, wherein, when the program code is executed by the processor, the program code causes the processor to set the threshold.

54. An apparatus according to claim 49, further comprising the capacitor.

55. A live tank breaker comprising the apparatus of claim 49 and the capacitor.

56. A dead tank breaker comprising the apparatus of claim 49 and the capacitor.

57. An apparatus for monitoring state of a high voltage capacitor, the capacitor comprising a sealed enclosure and a plurality of capacitor elements within the enclosure, the apparatus comprising:
a pressure sensor configured to measure pressure within the enclosure to obtain measured pressure;
a processing module coupled to the pressure sensor, the processing module comprising:
a comparator configured to compare the measured pressure to a threshold, and to generate an indication of capacitor failure in response to the measured current exceeding the threshold.

58. An apparatus according to claim 57, wherein the comparator is implemented in a processor configured to execute program code stored in a memory module.

59. An apparatus according to claim 58, wherein the processing module further comprises a radio frequency transmitter configured to transmit the indication of capacitor failure.

60. An apparatus according to claim 59, wherein the processing module further comprises a radio frequency receiver configured to receive an interrogation request, and the transmitter is configured to transmit the indication in response to the interrogation request.

61. An apparatus according to claim 57, wherein the threshold is set substantially at ten percent of the rated pressure of the enclosure.

62. An apparatus according to claim 57, wherein the threshold is set substantially at ten bars.

63. An apparatus according to claim 57, wherein the threshold is set substantially at twenty bars.

64. An apparatus according to claim 57, further comprising the capacitor.

65. A live tank breaker comprising the apparatus of claim 57 and the capacitor.

66. A dead tank breaker comprising the apparatus of claim 57 and the capacitor.
